(19) United States
(12) Patent Application Publication
(10) Pub. No.: US 2009/0052139 A1
(43) Pub. Date: Feb. 26, 2009

(54) Heat-Dissipation Apparatus For Communication Device With Card Slot

(76) Inventors: Kuping Lai, Hsinchu (TW); Moan Young, Hsinchu (TW)

Correspondence Address: LIN & ASSOCIATES INTELLECTUAL PROPERTY, INC., P.O. BOX 2339, SARATOGA, CA, 95070-0339, US

(21) Appl. No.: 11/844,297

(22) Filed: Aug. 23, 2007

(51) Int. Cl. H05K 7/20

(52) U.S. Cl. 361/707

(57) ABSTRACT

A heat dissipation apparatus for communication device with card slot is provided. The heat dissipation apparatus is applicable to a communication platform to dissipate the heat generated by the card communication module to the housing case. The heat dissipation apparatus includes a heat-conductive bridge, and at least a soft heat-conductive plate. The soft heat-conductive plate covers the surface of the card communication module to conduct the heat generated by the chips of the card communication module to the heat-conductive bridge, and then to the metal housing case for dissipation.

### FIELD OF THE INVENTION

The present invention generally relates to a heat dissipation apparatus for communication device with card slot, applicable to a communication platform to dissipate the heat generated by a card communication module to the housing case.

### BACKGROUND OF THE INVENTION

The worldwide interoperability for microwave access (Wi-Max) and wireless fidelity (Wi-Fi) technologies enables the establishing of wireless communication network in the metropolitan area. In general, this type of wireless communication device is installed outdoors, and usually without built-in fan for heat dissipation.

To facilitate the flexibility and the expandability of the wireless communication devices, the wireless network module can employ card wireless communication module, such as card bus, Mini Peripheral Component Interconnect (Mini PCI), USB, Peripheral Component Interconnect (PCI), and Personal Computer Memory Card International Association (PCMCIA) so that the wireless network module can be easily upgraded.

The current outdoor wireless communication devices must withstand the harsh environment, including the rapid changes of temperature and humidity, torching sun and even pouring rain. The heat dissipation capability and the system stability are the key to the function of the wireless communication devices. Therefore, the heat dissipation for the card wireless communication module inside the wireless communication device is an important issue. The conventional solution for heat dissipation is to glue the heat dissipating pad on the wireless chips of the card wireless communication module. However, as the card wireless communication module is inserted in the card slot on the PCB in the parallel direction, the communication device is under constant sun exposure, and the internal space of the communication device is enclosed, the heat generated by the card wireless communication module can not be easily vented out. As a result, the over-heated internal space may cause the failure of the circuit, and the system.

### SUMMARY OF THE INVENTION

The primary object of the present invention is to provide a heat dissipation apparatus for communication device with card slot. The present invention is applicable to a wireless communication platform that supports card communication modules, and is designed to dissipate the heat generated by the card communication module to the housing case of the communication device.

The communication device with card slot of the present invention includes a main PCB, at least a card communication module embedded on the main PCB, and a metal housing case. The main PCB and the card communication module are both inside the metal housing case. The heat dissipation apparatus of the present invention includes a heat-conductive bridge. The heat-conductive bridge of the heat dissipation apparatus is placed on and contacts the card communication module so that the heat generated by the card communication module can be transferred to the heat-conductive bridge, and then to the metal housing case.

The heat dissipation apparatus of the present invention may further includes at least a soft heat-conductive plate. The heat-conductive plate covers the surface of the card communication module so that the heat generated by the chips can be transferred to the heat-conductive bridge, and then to the metal housing case.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of a heat dissipation apparatus for communication device with card slot of the present invention;

FIG. 2 shows a schematic view of a heat dissipation apparatus of the present invention including a soft heat-conductive plate;

FIG. 3 shows an exploded view of the heat dissipation apparatus including a soft heat-conductive plate of FIG. 2;

FIG. 4 shows a schematic view of the present invention after assembled; and

FIG. 5 shows a schematic view of using a flat antenna board as the top cover of the metal housing case of the communication device.

### DETAILED DESCRIPTION OF THE PREFERRED EMBODIMENTS

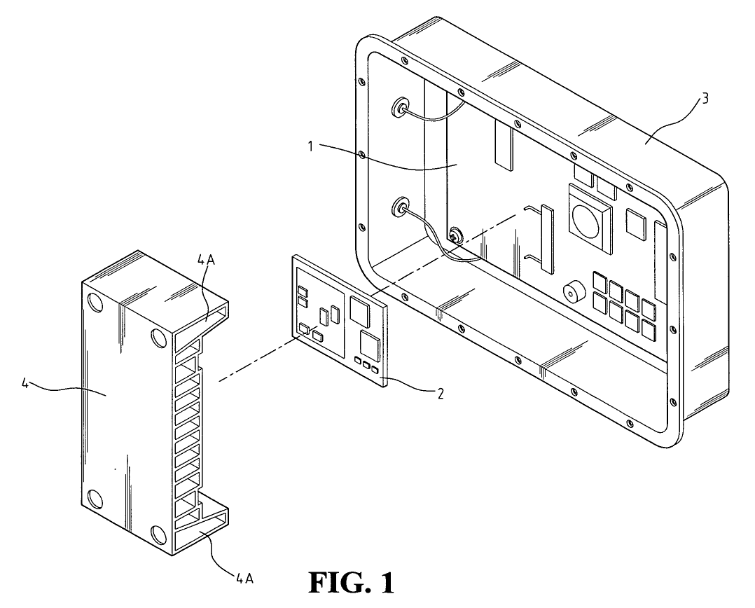

FIG. 1 shows a schematic view of the heat dissipation apparatus for communication device with card slot. As shown in FIG. 1, the communication device with card slot includes a main PCB 1, at least a card communication module 2, such as mini PCI module, inserted in a card slot on main PCB 1, and a metal housing case 3. In this architecture, card communication module 2 is a daughter card of main PCB 1. Main PCB 1 and card communication module 2 are both inside metal housing case 3. The heat dissipation apparatus of the present invention includes a heat-conductive bridge 4.

Heat-conductive bridge 4 is placed on and contacts card communication module 2. Heat-conductive bridge 4 crosses main PCB 1. The two wings 4A of heat-conductive bridge 4 contacts the inside surface of metal housing case 3 so that the heat generated by card communication module can be transferred to metal housing case 3 through heat-conductive bridge 4 for dissipation.

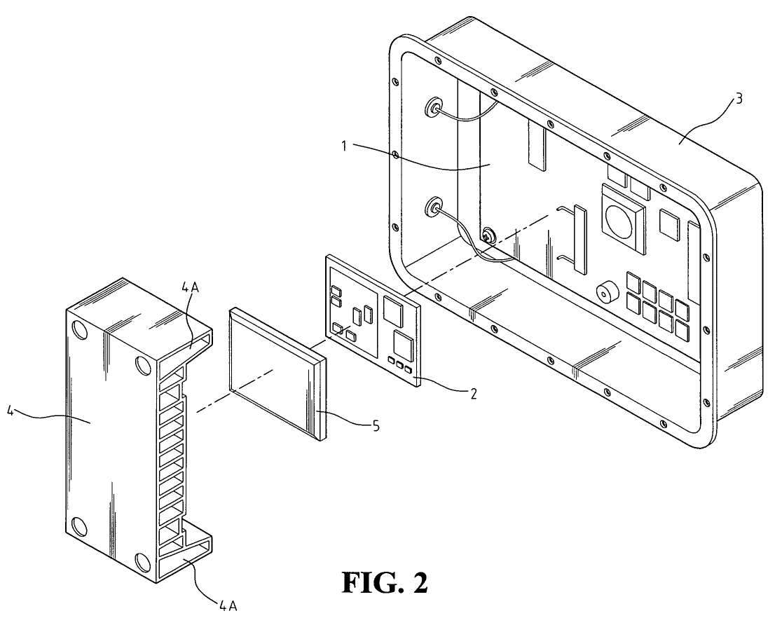

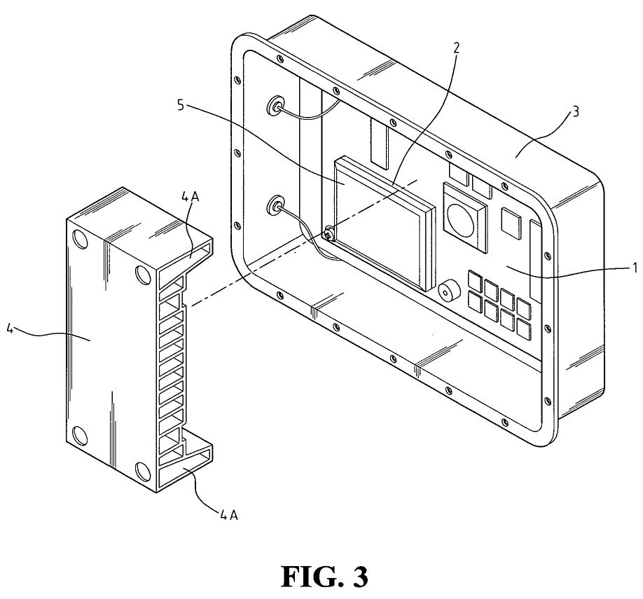

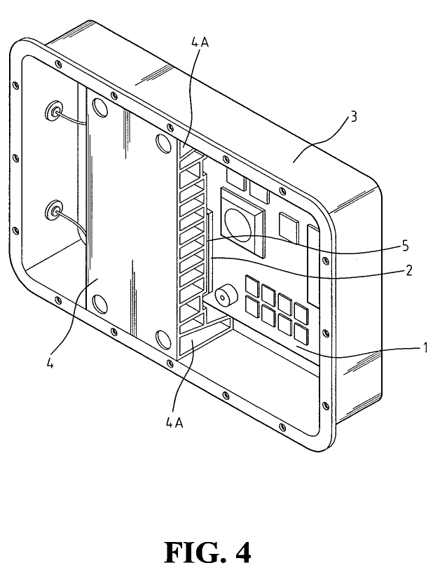

The heat dissipation apparatus of the present invention can further include at least a soft heat-conductive plate, as shown in FIG. 2. Soft heat-conductive plate 5 is placed between card communication module 2 and heat-conductive bridge 4, and covers the surface of card communication module 2, as shown in FIG. 3. In this manner, the heat generated by card communication module 2 can be transferred to metal housing case 3 through soft heat-conductive plate 5 and heat-conductive bridge 4 for dissipation. FIG. 4 shows a schematic view of the heat dissipation apparatus for communication device with card slot after assembled.

Soft heat-conductive plate 5 covers the upper surface of card communication module. As heat-conductive plate 5 is soft, heat-conductive plate 5 can contact the surface of all the chips on card communication module 2 regardless of the height of the chips. After soft heat-conductive plates 5 transferring the heat from the chips to heat-conductive bridge 4, heat-conductive bridge 4 transfers the heat to metal housing case 3 for dissipation to the outside. With this type of heat conduction, the heat generated by different chips of different height can also be dissipated through soft heat-conductive plates 5 and heat-conductive bridge 4 to metal housing case 3. When a different card communication module 2 is used to replace the old card communication module in the daughter card slot, the soft heat-conductive plate 5 can be tailored to fit the shape of the new card communication module 2.

It is worth noting that soft heat-conductive plate 5 can be made of heat-conductive silicon, and heat-conductive bridge 4 can be made of high heat-conductive metal, such as aluminum, aluminum alloy, or copper. A heat-conductive silicon or glue (not shown in the figures) can be applied to the surface between two wings 4A of heat-conductive bridge 4 and metal housing case 3 to facilitate the heat transfer. Heat-conductive bridge 4 can clap or be crewed onto metal housing case 3.

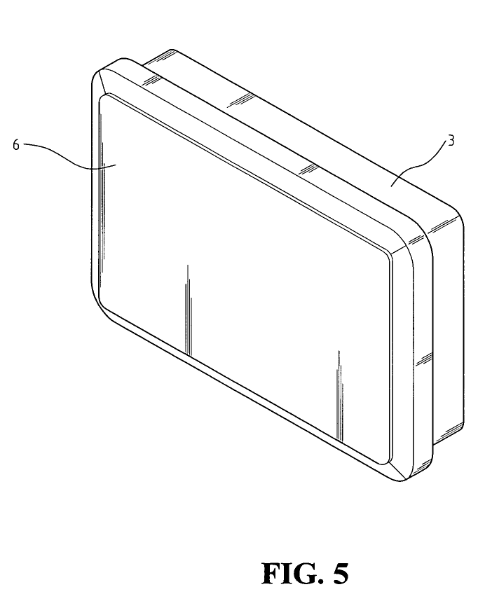

As shown in FIG. 5, the communication device usually uses a flat antenna board 6 to improve the communication quality. Flat antenna board 6 can be placed on the surface of metal housing case or as the top cover of the communication device. With such a structure, the card communication module can not dissipate the heat through the top cover of the metal housing case. However, the heat-conductive bridge of the present invention can successfully dissipate the heat from card communication module to both sides of the metal housing case to the outside.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A heat dissipation apparatus for communication device with card slot, said communication having a main PCB, at least a card communication module inserted in a card slot of said main PCB, and a metal housing case, said man PCB and said card communication module being inside said metal housing case, said heat dissipation apparatus comprising:
a heat-conductive bridge;
wherein said heat-conductive bridge being placed on and contacting said card communication module, two wings of said heat-conductive bridge contacting said metal housing case so as to transfer heat generated by said card communication module to said metal housing case for dissipation to outside.

2. The heat dissipation apparatus as claimed in claim 1, further comprising at least a soft heat-conductive plate placed between each said card communication module and said heat-conductive bridge, said soft heat-conductive plate covering each said card communication module so as to transfer the heat generated by said card communication module to said heat-conductive bridge, and then to metal housing case for dissipation to outside.

3. The heat dissipation apparatus as claimed in claim 2, wherein said soft heat-conductive plate is made of heat-conductive silicon or other soft heat-conductive material.

4. The heat dissipation apparatus as claimed in claim 1, wherein said heat-conductive bridge is made of aluminum, aluminum alloy or copper.

5. The heat dissipation apparatus as claimed in claim 1, wherein a heat-conductive glue can be applied to the contact points between said two wings of said heat-conductive bridge and said metal housing case.

6. The heat dissipation apparatus as claimed in claim 1, wherein a heat-conductive silicon can be inserted at the contact points between said two wings of said heat-conductive bridge and said metal housing case.

7. The heat dissipation apparatus as claimed in claim 1, wherein said card communication module is a wireless communication module of various protocols and specifications, including card bus, mini PCI, PCMCIA, and PCI.
